(19) United States
(12) Patent Application Publication
(10) Pub. No.: US 2025/0372574 A1
(43) Pub. Date: Dec. 4, 2025

(54) METHOD AND APPARATUS FOR MANUFACTURING ELECTRONIC DEVICE

(71) Applicant: ABLEPRINT TECHNOLOGY CO., LTD., Hsinchu (TW)

(72) Inventor: Shih-Hao Lee, Hsinchu (TW)

(21) Appl. No.: 19/199,355

(22) Filed: May 5, 2025

(30) Foreign Application Priority Data
May 31, 2024 (TW) 113120190

(51) Int. Cl. H01L 23/00

(52) U.S. Cl. CPC H01L 24/83; H01L 24/75; H01L 2224/75102; H01L 2224/7525; H01L 2224/755; H01L 2224/759; H01L 2224/83048; H01L 2224/8309; H01L 2224/83102; H01L 2224/83986

(57) ABSTRACT

A method for manufacturing an electronic device includes the following steps: providing a carrier board; providing an electronic device; fixing a conductive block located on at least one surface of the electronic device to the carrier board to form an integral assembly; placing the integral assembly into a processing chamber; reducing a temperature in the processing chamber to a first predetermined temperature lower than normal temperature; reducing a pressure in the processing chamber to a first predetermined pressure which is a vacuum pressure, and maintaining the vacuum pressure for a predetermined time; increasing the pressure in the processing chamber to a second predetermined pressure no less than 1 atm, and maintaining the second predetermined pressure for a predetermined time; and increasing the temperature in the processing chamber to a second predetermined temperature. The present disclosure also relates to an apparatus for manufacturing an electronic device.

### CROSS REFERENCE TO RELATED APPLICATIONS

The present application claims the benefit of Taiwanese Patent Application No. 113120190 filed on May 31, 2024, the contents of which are incorporated herein by reference in their entirety.

### TECHNICAL FIELD

The present disclosure relates to a method and an apparatus for manufacturing an electronic device.

### BACKGROUND

In the manufacturing process for conventional electronic devices (such as chips), an electronic device is usually fixed on a carrier board through a plurality of conductive blocks, then a capillary underfill is applied from one or more side edges of the electronic device, and this capillary underfill creeps along a gap between the electronic device and the carrier board and fill this gap, so that the capillary underfill can coat and isolate the conductive blocks located between the electronic device and the carrier board. However, there are usually many tiny bubbles in this capillary underfill. This capillary underfill creeps along one or more side edges of the electronic device in the process of filling this gap. Front edges of this capillary underfill form an incompletely filled space due to various factors during advancement. Specifically, when the capillary underfill advances from at least one side edge of the electronic device towards the other end of the electronic device, the incompletely filled space is formed due to various factors, such as inconsistent flow rates of the capillary underfill creeping on the front edges or bubbles formed due to problems such as a back-wrapping space, which we call “back-wrapping phenomenon”, caused by meeting of the front edges on which the capillary underfill creeps. The bubbles generated by this phenomenon and the many tiny bubbles in the capillary underfill eventually form voids in the capillary underfill.

The conventional method for removing bubbles is to eliminate the bubbles by increasing the temperature and vacuuming. However, such a method is not the best recommendation for bubble removal in Chiplet package and system in a package (SiP, multi-chip package) of advanced package and underfills made from low-temperature materials. The higher the temperature is, the lower the viscosity of the adhesive is, and the higher the flowability is, which will increase the risk of the adhesive overflowing outside the electronic device and creeping onto the electronic device, thus causing defects of adhesive overflowing and creeping. In addition, the polymer material has the characteristic of easy diffusion, so that during bubble removal, excessive material extraction is likely to occur due to a vacuum pressure difference inside and outside the bubbles.

Therefore, in view of the problems existing in the above conventional structure, developing an innovative structure with more ideal practicality is eagerly anticipated by consumers and is also the goal and direction that relevant practitioners must strive to achieve through research and development.

In view of this, based on years of experience in manufacturing, development and design of related products, the inventor, after detailed design and careful evaluation aiming at the above goal, has finally obtained the present disclosure which is truly practical.

### SUMMARY

To solve the above problems, according to an embodiment of the present disclosure, a method for manufacturing an electronic device is provided, including the following steps: providing a carrier board with a first surface; providing an electronic device provided with a conductive block on at least one surface thereof, fixing the conductive block located on the at least one surface of the electronic device to the first surface of the carrier board to form an integral assembly; applying a capillary underfill from at least one side edge of the electronic device, and allowing the capillary underfill to creep along a gap between the electronic device and the carrier board and fill the gap, thus forming protection for the conductive block; placing the integral assembly into a processing chamber; reducing a temperature in the processing chamber to a first predetermined temperature lower than normal temperature; reducing a pressure in the processing chamber to a first predetermined pressure which is a vacuum pressure, and maintaining the vacuum pressure for a predetermined time; increasing the pressure in the processing chamber to a second predetermined pressure no less than 1 atm, and maintaining the second predetermined pressure for a predetermined time; and increasing the temperature in the processing chamber to a second predetermined temperature.

The first predetermined temperature and the first predetermined pressure can avoid the risk of excessive overflow of the capillary underfill outside the electronic device and the problems such as the adhesive creeping onto the electronic device, and help to reduce the volume of bubbles caused by a back-wrapping phenomenon resulting from the application of the capillary underfill from multiple side edges of the electronic device; and the second predetermined temperature and the second predetermined pressure can be used to completely eliminate the bubbles with the reduced volume in the gap between the electronic device and the carrier board through gas dissolution and diffusion. The second predetermined temperature and the second predetermined pressure can be changed in parameters and sequence according to process requirements, so that the bubbles generated by the back-wrapping phenomenon can be eliminated in order from large to small.

In addition, as described above, the polymer material has the characteristic of easy diffusion. Therefore, as long as removal of the bubbles does not cause excessive material extraction due to a vacuum pressure difference inside and outside the bubbles, the greater the pressure difference is, the faster the bubble removal is. Reducing the temperature of the material, i.e., increasing the viscosity of the material, is an action taken to prevent the material from being extracted in the process of removing the bubbles in the material. Although increasing the viscosity of the material will reduce the speed of bubble removal, from a microscopic perspective, before the material is completely aged, increasing the vacuum pressure difference inside and outside the bubbles can make the bubbles penetrate into the material (dissolve) more quickly and remove the bubbles through a moving force towards the edges of the electronic device generated by a concentration gradient.

Regarding the technologies and means adopted by the present disclosure and the effects thereof, a preferred embodiment is hereby cited and will be described in detail below with reference to the drawings. It is believed that the above objectives, structures and features of the present disclosure can be deeply and specifically understood thereby.

### BRIEF DESCRIPTION OF THE DRAWINGS

FIG. 1 shows a flowchart of a method for manufacturing an electronic device according to an embodiment of the present disclosure;

FIG. 2 shows a schematic diagram of an apparatus for manufacturing an electronic device according to an embodiment of the present disclosure;

FIGS. 3A to 3C show schematic diagrams of a manufacturing process for an electronic device;

FIG. 3D shows a schematic diagram of a back-wrapping phenomenon generated when front edges of a capillary underfill meet in a three-edge filling process;

FIG. 3E shows a schematic diagram of a stress condition of bubbles in a material of a capillary underfill in a process of removing the bubbles by means of a vacuum pressure difference;

FIGS. 4A and 4B show schematic diagrams of different filling methods for a capillary underfill respectively; and

FIG. 5 shows a diagram of a relationship among a process temperature, a process pressure, and process time according to an embodiment of the present disclosure.

### DETAILED DESCRIPTION OF THE EMBODIMENTS

To make your esteemed examination committee have a further understanding and recognition of the objectives, features and effects of the present disclosure, the following detailed description is provided in conjunction with the embodiments and drawings:

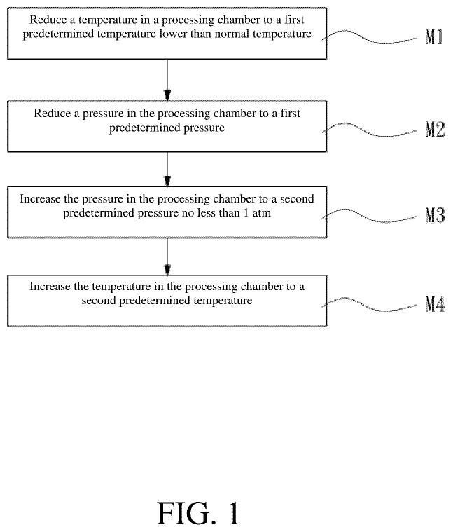

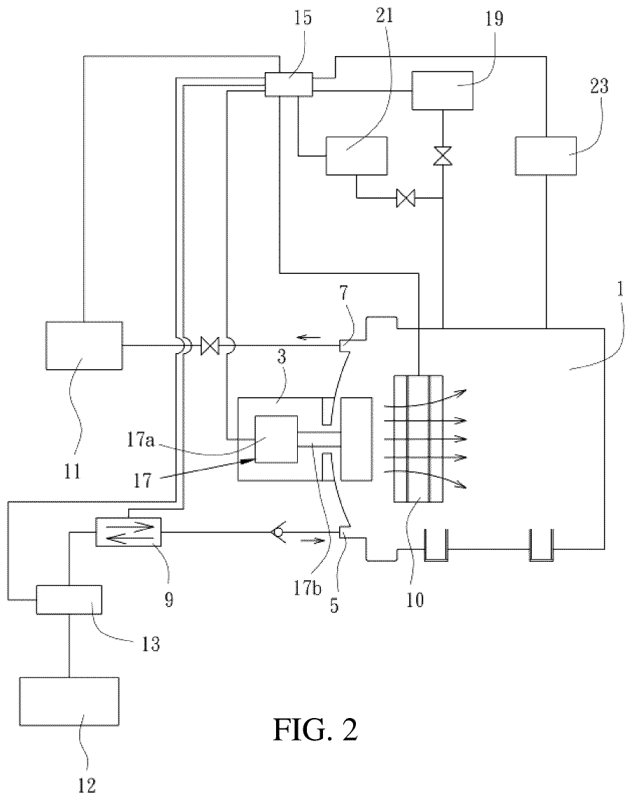

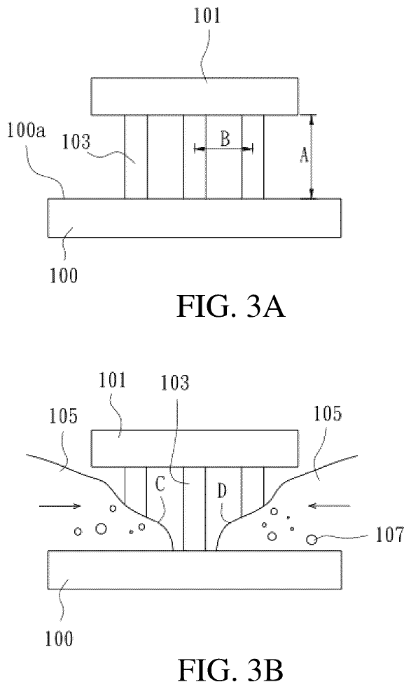

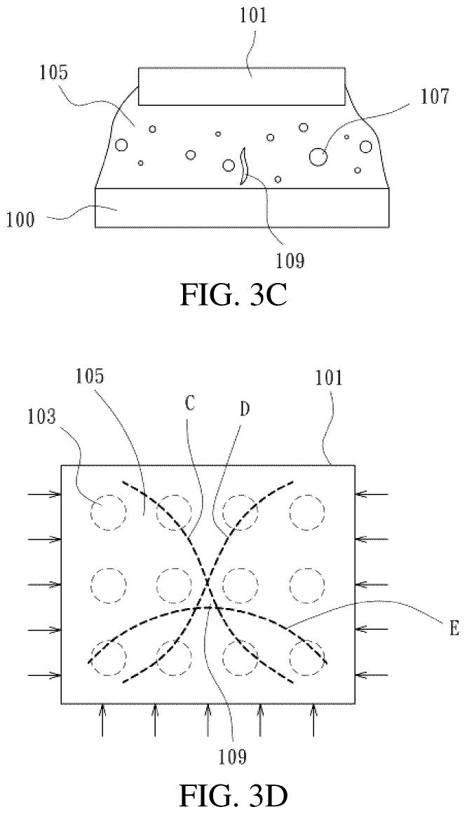

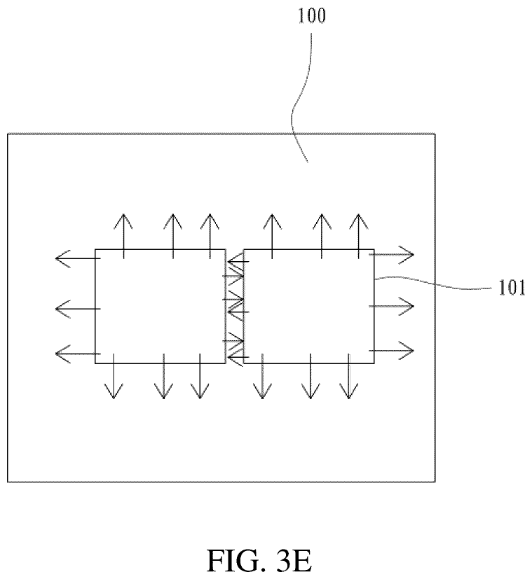

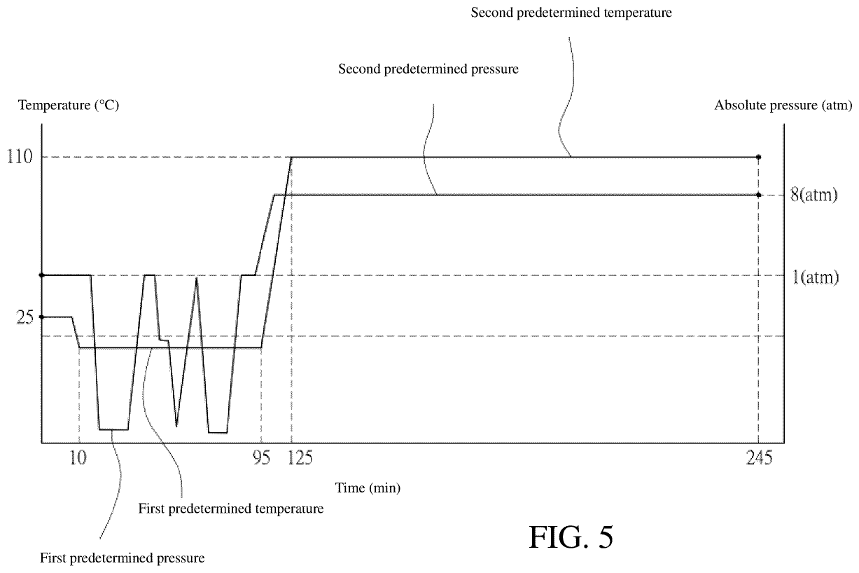

According to an embodiment of the present disclosure, referring to FIGS. 3A to 3C, a method for manufacturing an electronic device is provided, including the following steps:
providing a carrier board 100 with a first surface 100a; providing an electronic device 101, where a conductive block 103 is provided on at least one surface of the electronic device 101; fixing the conductive block 103 located on the at least one surface of the electronic device 101 to the first surface 100a of the carrier board 100 to form an integral assembly, where there is a spacing B between conductive blocks 103, and there is a gap A between the electronic device 101 and the carrier board 100; applying a capillary underfill 105 from at least one side edge of the electronic device 101, and allowing the capillary underfill 105 to creep along the gap A between the electronic device 101 and the carrier board 100 and fill the gap A, so that the capillary underfill 105 can coat and isolate the conductive block 103 between the electronic device 101 and the carrier board 100, thus forming protection for the conductive block 103; then, placing the integral assembly into a processing chamber 1 shown in FIG. 2; referring to FIG. 1 and FIG. 5, reducing a temperature in the processing chamber 1 to a first predetermined temperature lower than normal temperature, so as to increase the viscosity of the capillary underfill 105, that is, to reduce the flowability of the capillary underfill 105; reducing a pressure in the processing chamber 1 to a first predetermined pressure which is a vacuum pressure, and maintaining the vacuum pressure for a predetermined time, so as to remove most of bubbles 107 and a bubble (a back-wrapping space) 109 or reduce the volume of the bubbles; next, increasing the pressure in the processing chamber 1 to a second predetermined pressure no less than 1 atm, and maintaining the second predetermined pressure for a predetermined time; and increasing the temperature in the processing chamber 1 to a second predetermined temperature, so as to age the capillary underfill and/or further remove residual bubbles 107 and the bubble (the back-wrapping space) 109 by increasing the flowability of the capillary underfill 105. For example, in an embodiment of the present disclosure, the second predetermined pressure may be no less than 1 atm and less than or equal to 50 atm, but is not limited thereto.

FIG. 5 shows an exemplary diagram of a relationship among a process temperature, a process pressure, and process time according to an embodiment of the present disclosure. It should be understood that the process parameters shown in FIG. 5 are only exemplary and do not limit the present disclosure.

In an embodiment of the present disclosure, the first predetermined temperature can be reduced to a value between below normal temperature (30° C.) and −40° C.; the second predetermined temperature can be between 40° C. and 300° C.; the first predetermined pressure can be reduced to a value between below 1 atm and 104 torr; and the second predetermined pressure can be between no less than 1 atm and 50 atm. In an embodiment of the present disclosure, Step 1 (M1) can include: reducing a temperature in a processing chamber 1 to a first predetermined temperature. Step 2 (M2) includes: reducing a pressure in the processing chamber 1 to a first predetermined pressure which is a vacuum pressure, and maintaining the vacuum pressure for a predetermined time. Step 3 (M3) can include: increasing the pressure in the processing chamber 1 to a second predetermined pressure no less than 1 atm, and maintaining the second predetermined pressure for a predetermined time. Step 4 (M4) can include: increasing the temperature in the processing chamber 1 to a second predetermined temperature.

FIGS. 3A to 3C show schematic diagrams of a manufacturing process for an electronic device. As shown in FIGS. 3A to 3C, in the manufacturing process for the electronic device, a conductive block 103 located on at least one surface of the electronic device 101 is fixed to a first surface 100a of a carrier board 100 (FIG. 3A), then a capillary underfill 105 is applied from at least one side edge of the electronic device 101 (FIG. 3B), and the capillary underfill 105 creeps along a gap between the electronic device 101 and the carrier board 100 and flow in this gap to fill this gap, thus forming protection for the conductive block 103 (FIG. 3C). However, there are usually many tiny bubbles 107 in the capillary underfill 105 and a bubble (a back-wrapping space) 109 formed due to a back-wrapping phenomenon when front edges of the capillary underfill meet. Subsequently, these bubbles 107 and the bubble (the back-wrapping space) 109 will form voids in the capillary underfill, and these voids will lead to problems such as a decrease in the reliability of the electronic device and electrical failure. As shown in FIG. 3D, in the process of filling this gap with the capillary underfill 105, the capillary underfill 105 creeps along three side edges of the electronic device 101. When the front edges C, D, and E of this capillary underfill meet during advancement, an incompletely filled space [i.e., the bubble (the back-wrapping space) 109 in FIG. 3C] is formed. As is well known, after the problem of void formation in the capillary underfill 105 is solved by using a high temperature and a high pressure, the problem of the capillary underfill 105 creeping onto the electronic device 101 due to the increased flowability in the bubble removal process arises. Therefore, in order to solve this problem, the temperature is reduced to below normal temperature to increase the viscosity of the capillary underfill 105, and then a vacuum is created, which can avoid the problem of the capillary underfill 105 creeping onto the electronic device 101. The function of the vacuum on the bubbles is not only to cause motion and pulling of the bubbles due to Newton's laws of motion, but also to enhance the effects of dissolution and diffusion. The process of first reducing the temperature to below normal temperature to increase the viscosity of the capillary underfill 105 and then creating a vacuum is more suitable for Chiplet package with a tiny gap between chips. This process can avoid creeping of the capillary underfill 105 during removal of bubbles in a tiny gap between the electronic device 101 and the electronic device 101. It is suitable for bubble removal in Chiplet package, multi-chip package, system in package (SiP), and the capillary underfill 105 as an underfill made from a low-temperature material. The capillary underfill is a polymer material, and gas molecules easily diffuse in the polymer material. Therefore, as long as removal of the bubbles does not cause extraction of the polymer material due to a vacuum pressure difference inside and outside the bubbles, the greater the pressure difference is, the faster the bubble removal is. FIG. 3E shows a schematic diagram of a stress condition of bubbles in a material of a capillary underfill 105 in a process of removing the bubbles by means of a vacuum pressure difference. Reducing the temperature of the polymer material, i.e., increasing the viscosity of the polymer material, is an action taken to prevent the polymer material from being extracted in the process of removing the bubbles in the polymer material. Generally, the process after the temperature-reducing vacuum bubble removal process will further include increasing the temperature and creating a high-pressure environment as vacuum bubble removal may not completely remove all the bubbles. In this way, the high temperature can reduce the viscosity of the capillary underfill 105, and the high pressure can promote dissolution and diffusion of the bubbles, which helps to shrink or even eliminate the bubbles.

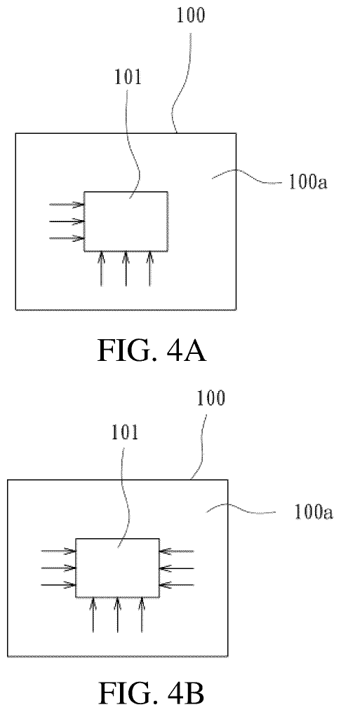

In an embodiment of the present disclosure, at least one of the methods shown in FIGS. 4A and 4B can be used to apply the capillary underfill 105 from the at least one side edge of the electronic device 101, and the capillary underfill 105 creeps along the gap A between the electronic device 101 and the carrier board 100 and fill the gap A. Although FIGS. 4A and 4B show rectangular carrier board 100 and electronic device 101, the present disclosure can be applied to carrier boards and electronic devices in various shapes. In an embodiment of the present disclosure, the electronic device 101 may be, for example, a chip.

An apparatus for manufacturing an electronic device according to an embodiment of the present disclosure is as shown in FIG. 2. This manufacturing apparatus can be connected to a facility pressure 12, that is, an external pressure source. “The facility pressure” generally refers to a pressure provided by a facility in a factory. This manufacturing apparatus can include: a processing chamber 1 for processing, having an extended space 3, one or more gas inlets 5, and one or more gas outlets 7, where the extended space 3 communicates with the processing chamber 1, and the gas inlets 5 are connected to the facility pressure 12; a cooler 9, mounted outside the processing chamber 1 and connected to the processing chamber 1 through a pipeline; a heater 10, mounted in the processing chamber 1; a vacuum generator 11, mounted outside the processing chamber and connected to the processing chamber 1 through the gas outlets 7; a controller 15; and a fan 17, configured to generate an airflow flowing towards the inside of the processing chamber 1. The cooler 9, the heater 10, the vacuum generator 11, and the fan 17 can be electrically connected to the controller 15 and transmit signals, thereby being controlled by the controller 15. The controller 15 can be configured to perform the following steps: reduce, by the cooler 9, a temperature in the processing chamber 1 to a first predetermined temperature lower than normal temperature, so as to increase the viscosity of a capillary underfill 105; reduce, by the vacuum generator 11, a pressure in the processing chamber 1 to a first predetermined pressure which is a vacuum pressure, and maintaining the vacuum pressure for a predetermined time, so as to remove most of bubbles 107 and a bubble (a back-wrapping space) 109 or reduce the volume of the bubbles; increase, by the external pressure source, the pressure in the processing chamber 1 to a second predetermined pressure no less than 1 atm, and maintaining the second predetermined pressure for a predetermined time; and increase, by the heater 10 and the fan 17, the temperature in the processing chamber 1 to a second predetermined temperature, so as to age the capillary underfill 105 and/or further remove residual bubbles 107 and the bubble (the back-wrapping spaces) 109 by increasing the flowability of the capillary underfill 105.

In an embodiment of the present disclosure, the controller 15 may be a programmable logic controller (PLC). In an embodiment of the present disclosure, the external pressure source (i.e., the facility pressure 12) can, for example, be connected to a pressure regulating element 13. The pressure regulating element 13 can be electrically connected to the controller 15 and transmit a signal, so as to be controlled by the controller 15 to complete setting of the predetermined pressure in the processing chamber 1. When the external pressure source (the facility pressure) is insufficient or unstable, the pressure regulating element 13 can be used to strengthen or stabilize the pressure leading to the inside of the processing chamber 1, so as to cause the pressure in the processing chamber 1 to reach and be maintained at the second predetermined pressure no less than 1 atm. In an embodiment of the present disclosure, the pressure regulating element 13 may be a component such as a pressure pump or a pressure cylinder. This manufacturing apparatus can further include: a vacuum sensor 19, connected to the inside of the processing chamber 1 and configured to detect the vacuum pressure in the processing chamber 1; a pressure sensor 21, connected to the inside of the processing chamber 1 and configured to detect the pressure in the processing chamber 1; and a temperature sensor 23, connected to the inside of the processing chamber 1 and configured to detect the temperature in the processing chamber 1. The vacuum sensor 19, the pressure sensor 21, and the temperature sensor 23 can be electrically connected to the controller 15 and transmit signals, so as to be controlled by the controller 15.

In an embodiment of the present disclosure, the vacuum sensor 19 may be, for example, a vacuum gauge, and the pressure sensor 21 may be, for example, a pressure gauge. In an embodiment of the present disclosure, the vacuum generator 11 may be, for example, a vacuum pump. As mentioned above, the fan 17 can be configured to generate the airflow flowing towards the inside of the processing chamber 1, so as to promote regulation of the temperature in the processing chamber 1. For example, when a heating function of the heater 10 is activated, a convective heating effect can be achieved, and when a cooling function of the cooler 9 is activated, a convective cooling effect can be achieved. The fan 17 is located in the processing chamber 1 and is connected to a driving motor 17a through a transmission shaft 17b, where the driving motor 17a is disposed in the extended space 3 communicating with the processing chamber 1, and the processing chamber 1 and the extended space 3 are of a shaft-seal-free design.

In an embodiment of the present disclosure, pressure and/or temperature regulation can be achieved by the controller 15. When the pressure inside the processing chamber 1 is reduced to a predetermined vacuum pressure, the controller 15 can first activate a set vacuum value and instruct the vacuum generator 11 to evacuate the inside of the processing chamber. Then, when the controller 15 receives a measurement signal from the vacuum sensor 19 indicating that the pressure inside the processing chamber has dropped to the set vacuum value, the vacuum generator 11 stops operating. Certainly, as mentioned above, this method can also be used to perform operation of increasing the pressure inside the processing chamber 1 or operation of increasing/reducing the temperature inside the processing chamber 1.

In addition, as mentioned above, linear pressure and/or temperature regulation can also be achieved under the control of the controller 15. For example, a linear rising/falling curve function can be used to design the controller 15, so that the pressure and/or temperature inside the processing chamber can be regulated in a linear rising/falling manner. Since the design of the controller is well-known to those skilled in the art of automatic control, the design principle and method thereof will not be repeated herein.

The foregoing provides a detailed description of the technical features of the present disclosure with respect to the preferred embodiments of the present disclosure. However, those skilled in the art can make changes and modifications to the present disclosure without departing from the spirit and principle of the present disclosure, and such changes and modifications shall all be covered within the scope defined by the following claims.

### DESCRIPTION OF REFERENCE SIGNS

1 processing chamber
3 extended space
5 gas inlet
7 gas outlet
9 cooler
10 heater
11 vacuum generator
12 facility pressure
13 pressure regulating element
15 controller
17 fan
17a driving motor
17b transmission shaft
19 vacuum sensor
21 pressure sensor
23 temperature sensor
100 carrier board
100a first surface
101 electronic device
103 conductive block
105 capillary underfill
107 bubble
109 bubble (back-wrapping space)
A gap
B spacing
C front edge of underfill
D front edge of underfill
E front edge of underfill
M1 Step 1
M2 Step 2
M3 Step 3
M4 Step 4

What is claimed is:

1. A method for manufacturing an electronic device, comprising the following steps:
providing a carrier board with a first surface; providing an electronic device provided with a conductive block on at least one surface thereof; fixing the conductive block located on the at least one surface of the electronic device to the first surface of the carrier board to form an integral assembly;
applying a capillary underfill from at least one side edge of the electronic device, and allowing the capillary underfill to creep along a gap between the electronic device and the carrier board and fill the gap, thus forming protection for the conductive block;
placing the integral assembly into a processing chamber; and adjusting a temperature and a pressure in the processing chamber, which comprises the following steps:
(a): reducing the temperature in the processing chamber to a first predetermined temperature lower than normal temperature, so as to increase the viscosity of the capillary underfill;
(b): reducing the pressure in the processing chamber to a first predetermined pressure which is a vacuum pressure, and maintaining the vacuum pressure for a predetermined time, so as to remove bubbles or reduce the volume of the bubbles;
(c): increasing the pressure in the processing chamber to a second predetermined pressure no less than 1 atm, and maintaining the second predetermined pressure for a predetermined time; and
(d): increasing the temperature in the processing chamber to a second predetermined temperature, so as to age the capillary underfill and/or further remove residual bubbles by increasing the flowability of the capillary underfill in conjunction with step (c).

2. The method for manufacturing an electronic device according to claim 1, wherein the first predetermined temperature is between below 30° C. and −40° C.

3. The method for manufacturing an electronic device according to claim 1, wherein the first predetermined pressure is between below 1 atm and 104 torr.

4. The method for manufacturing an electronic device according to claim 1, wherein the second predetermined temperature is between 40° C. and 300° C.

5. The method for manufacturing an electronic device according to claim 1, wherein the second predetermined pressure is between no less than 1 atm and 50 atm.

6. An apparatus for manufacturing an electronic device, connected to an external pressure source, and comprising:
a processing chamber, having an extended space, one or more gas inlets, and one or more gas outlets, wherein the extended space communicates with the processing chamber, and the gas inlets are connected to the external pressure source;
a cooler, mounted outside the processing chamber and connected to the processing chamber through a pipeline;
a heater, mounted in the processing chamber;
a vacuum generator, mounted outside the processing chamber and connected to the processing chamber;
a fan, configured to generate an airflow flowing inside the processing chamber; and
a controller, configured to perform the following steps:
reduce, by the cooler, a temperature in the processing chamber to a first predetermined temperature lower than normal temperature, so as to increase the viscosity of a capillary underfill;
reduce, by the vacuum generator, a pressure in the processing chamber to a first predetermined pressure which is a vacuum pressure, and maintaining the vacuum pressure for a predetermined time, so as to remove bubbles or reduce the volume of the bubbles;
increase, by the external pressure source, the pressure in the processing chamber to a second predetermined pressure no less than 1 atm, and maintaining the second predetermined pressure for a predetermined time; and
increase, by the heater and the fan, the temperature in the processing chamber to a second predetermined temperature, so as to age the capillary underfill and/or further remove residual bubbles by increasing the flowability of the capillary underfill.

7. The apparatus for manufacturing an electronic device according to claim 6, further comprising: a pressure regulating element, disposed between the external pressure source and the gas inlets, and configured to cause the pressure in the processing chamber to reach and be maintained at the second predetermined pressure.

8. The apparatus for manufacturing an electronic device according to claim 6, further comprising: a vacuum sensor, connected to the inside of the processing chamber, configured to detect the vacuum pressure in the processing chamber, and electrically connected to the controller.

9. The apparatus for manufacturing an electronic device according to claim 6, further comprising: a pressure sensor, connected to the inside of the processing chamber, configured to detect the pressure in the processing chamber, and electrically connected to the controller.

10. The apparatus for manufacturing an electronic device according to claim 6, further comprising: a temperature sensor, connected to the inside of the processing chamber, configured to detect the temperature in the processing chamber, and electrically connected to the controller.
